(19) United States
(12) Patent Application Publication
(10) Pub. No.: US 2005/0148123 A1
(43) Pub. Date: Jul. 7, 2005

(54) Method for fabricating self-aligned thin-film transistor

(76) Inventor: Huang Mao-Tsum, Tainan City (TW)

Correspondence Address: NATH & ASSOCIATES, 1030 15th STREET, NW, 6TH FLOOR, WASHINGTON, DC, 20005, US

(21) Appl. No.: 10/805,340

(22) Filed: Mar. 22, 2004

(30) Foreign Application Priority Data
Jan. 5, 2004 (TW) 093100186

(51) Int. Cl. H01L 21/00; H01L 21/84

(52) U.S. Cl. 438/158

(57) ABSTRACT

The present invention relates to a method for fabricating a self-aligned TFT (thin-film transistor). The method comprises depositing a metal layer on a substrate; patterning the metal layer with a desired gate pattern by photolithography and etching; forming a gate insulation layer, a semiconductor layer, an ohmic contact layer, and a transparent conductive layer on the substrate in sequence to form a multilayer structure; back exposing a negative photoresist layer formed on the transparent conductive layer with the gate pattern as a mask; removing the unexposed portion of the negative photoresist layer; and forming a drain and a source of a self-aligned TFT after performing a conventional process of a multi-layer semiconductor. The method of the present invention improves the problem of color mura (uneven hue) occurred in LCD which results from uneven parasitic capacitor (Cgd) inside LCD panel between the gate and the drain.

### BACKGROUND OF THE INVENTION

1. Field of the Invention

This invention relates to a method for fabricating a drain, a gate, and a source of a self-aligned TFT (thin-film transistor), and more particularly to a method for improving the color mura (uneven hue) of a liquid crystal display (LCD) device by using a transparent electrode and exposed from the reverse side (back side) of a substrate, for fabricating the drain, gate, and source of the self-aligned TFT.

2. Description of the Prior Art

The conventional method for manufacturing a TFT in the LCD device is shown in FIG. 1a, wherein a metal layer 2 is deposited on a substrate 1 and etched with a desired pattern as a gate, in general. After a gate insulator layer 3 is formed thereon, an amorphous silicon layer 4, an n+silicon layer 5, and a metal layer 6 are deposited on the substrates in sequence. Then, a positive photoresist layer 7 is coated on the metal layer 6, exposed through a mask 8 with another desired pattern, and developed to remove the exposed portion thereof. The metal layer 6 below the removed area of the photoresist layer 7 is etched, and then a channel A, a drain 61, and a source 62 are formed. After that, the unexposed portions of photoresist layer 7 are removed and a passivative layer 9 is blanket formed on the substrates to obtain a TFT (Thin-film transistor) structure as shown in FIG. 1b.

In the gate, the drain, and the source formation, different overlapping contacts will generate between the drain and the gate, and between the source and the gate if the mask is aligned incorrectly at the exposure step. This will even result in uneven parasitic capacitance (Cgd) inside LCD panel between the gate and the drain. It is still also the major cause of color mura (uneven hue) occurred in the LCD device. Since the size of the TFT is very small, at the level of micrometer, precise alignment for mask is difficult.

In order to improve mask alignment, U.S. Pat. No. 6,403,407B1 discloses a method for forming a fully self-aligned TFT. A metal layer is deposited on a substrate and etched with a desired pattern as a gate. After the metal gate is formed thereon, a first dielectric layer, a semiconductor layer, and a second dielectric layer are deposited on the substrate in sequence. The parts of the all layers corresponding with the metal gate are higher than other parts. After coating a positive photoresist layer on the second dielectric layer, in lithography back side exposure (exposure from the reverse side of substrate), the metal gate will be used as a mask. The unexposed portion of positive photoresist layer corresponding to metal gate is remained, and the other portion is removed by developing. The unprotected portion of the second dielectric layer is etched to form a channel insulation layer. Then, another metal layer is formed and another coated photoresist layer are formed on the substrate, and the part of the latter photoresist layer above the channel insulator layer is thinner than other parts due to the higher channel insulator layer. The photoresist layer is exposed with a half-tone mask, and the area of the metal layer is removed above channel insulator layer. A drain and a source are then formed.

The method using back exposure only can define the channel insulator layer aligned with the metal gate. Then, half-tone mask is used to process exposure. The method, however, still has the alignment problem, and the exposure process is too complicated.

In accordance with drawbacks mentioned above, there still needs a method for forming self-aligned drain, source, and gate of a TFT.

### SUMMARY OF THE INVENTION

Therefore, the present invention is provided in view of the above problems in the prior arts, and it is an objective of the present invention to provide a method for fabricating a self-aligned TFT. The present invention comprises the steps of: (i) forming a gate layer on a transparent substrate; (ii) forming an insulation layer, a semiconductor layer, and a transparent conductive layer in sequence to cover on the gate layer; (iii) forming a negative photoresist layer upon the transparent conductive layer and exposing the negative photoresist layer from the reverse side of the transparent substrate by using the gate layer as a mask; (iv) removing unexposed portions of the negative photoresist layer to uncover a portion of the transparent conductive layer; (v) etching the uncovered portion of the transparent conductive layer till a portion of the semiconductor layer is uncovered; (vi) removing the negative photoresist layer; (vii) coating a positive photoresist layer, and removing the unnecessary portion thereof by front exposure with a mask; and (viii) etching the portions of the semiconductor layer and the transparent conductive layer to form TFTs.

The present invention also provides a thin film transistor. The thin film transistor comprises a transparent substrate, a gate, an insulation layer, a semiconductor layer, and a transparent conductive layer. The gate, the insulation layer, the semiconductor layer, and the transparent conductive layer are formed on the transparent substrate in sequence. The transparent conductive layer has two separate portions, and the two portions are on two sides of the gate and the opening is above the gate.

In accordance with the present invention, the transparent conductive material layer is used for forming the drain and source in the step (ii). Taking the transparent character, the self-aligned objective can be achieved through the steps of using a negative photoresist (since exposure, the exposed portion is remained and the unexposed portion is removed by etching) layer, using the first metal layer (gate) as a mask to expose the negative photoresist layer from the back side of the substrate, and etching the portion corresponding to the gate. Furthermore, it helps to solve the uneven color problem, which is caused by unbalance gate and drain parasitic capacitance in the traditional exposure process.

In accordance with the present invention, due to the means of the back exposure and using transparent conductive material, the TFT process can be simplified, and further the precise alignments in drain, source, and gate of the TFT is obtained. Not only the product yield is increased, but also manufacturing cost is reduced.

### BRIEF DESCRIPTION OF THE DRAWINGS

FIGS. 1a and 1b illustrate the processes for fabricating a TFT in prior arts;

FIG. 2 is a schematic diagram illustrating a gate forming on a substrate;

FIG. 3 is a schematic diagram of the TFT multi-layer structure of forming a gate insulating layer, a semiconductor layer, an ohmic contact layer, and a transparent conductive material layer in sequence, and coating a negative photoresist layer, where the arrow represents light direction according to the present invention;

FIG. 4 is a schematic diagram of the TFT multi-layer structure of forming a channel by removing the portion of transparent conductive layer and ohmic contact layer corresponding to gate;

FIG. 5 is a schematic diagram of the TFT multi-layer structure of forming TFT islands by removing the portion of the semiconductor layer, the ohmic contact layer and the transparent conductive material layer;

FIG. 6 is a schematic diagram of the TFT multi-layer structure with drain wire and source wire at both opposite side of the transparent electrode which are formed from a second metal layer; and

FIG. 7 is a schematic diagram of the TFT multi-layer structure in accordance with this invention.

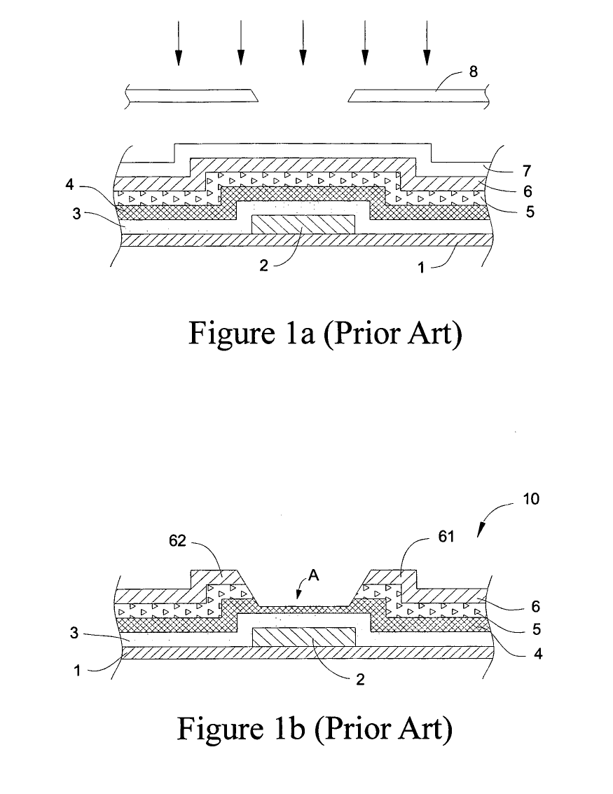

### DESCRIPTION OF THE PREFERRED EMBODIMENT

In the description of the present invention, “back exposure” or “exposure from the reverse side of substrate” means to perform exposure by illuminating from the back side of a TFT substrate.

In contrast to “front exposure”, it means to perform exposure by illuminating from the front side of the TFT substrate.

The method for fabricating a self-aligned TFT in the present invention will be described in more detail with the corresponding Figures.

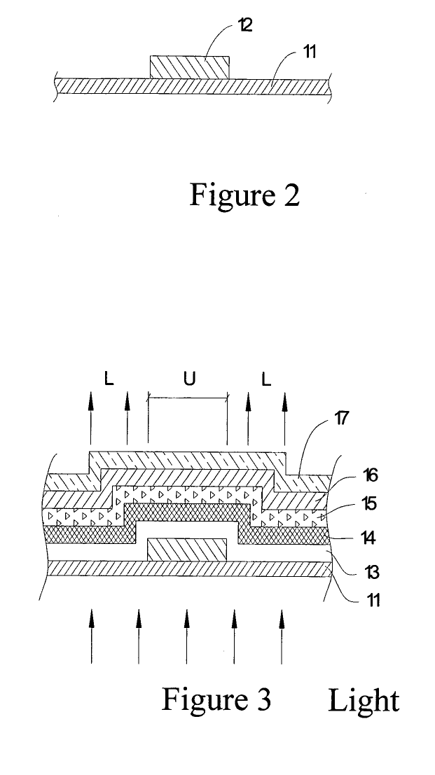

Please refer to FIG. 2, a metal layer 12 with a desired pattern is formed as gates on a substrate 11 by photolithography. The substrate 11 is a transparent material, such as glass, quartz, or plastics. In the field of manufacturing TFT, the gate 12 can be any conductive metal, such as a single layer of chromium (Cr), wolfram (W), aluminum (Al), copper (Cu), the alloy thereof, or other conductive material, or a multi layer of Cr/Al, Mo/Al and so on. The shape of the gate 12 in the present invention is not limited as shown in FIG. 2; its shape can be either topography, taper or other shape as well.

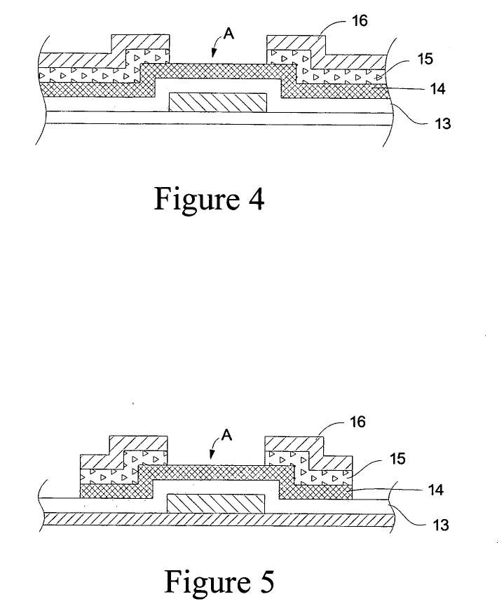

Please refer to FIG. 3, a gate insulator (GI) layer 13, a gate insulator, a semiconductor layer 14, an ohmic contact layer 15, and a transparent conductive material layer 16 are formed on the substrate in sequence. Then, a negative photoresist layer 17 is coated on the substrate 11. The portion U of the negative photoresist layer 17 is not exposed (since gate 12 is used as a mask, the upper portion of negative photoresist layer corresponding to the gate can not be exposed) and the portion L thereof is exposed to light by using back exposure (exposure from the reverse side of substrate 11, as shown in FIG. 3). The portion U of the negative photoresist layer 17 is removed by developing, and further the underneath transparent conductive material layer 16 and the ohmic contact layer 15 are also removed by etching to form a channel A in the semiconductor layer 14 corresponding to the gate 12. Then, the exposed portion L of the negative photoresist layer 17 is removed, as shown in FIG. 4.

Next, a positive photoresist layer is coated, and the unnecessary portion thereof is removed by front exposure with a mask. A partial of the conductive metal layer 16, ohmic contact layer 15, and semiconductor layer 14 out sides of gates are etched to form an island-shaped TFT, as shown in FIG. 5. As aforementioned, a TFT is now completed.

After forming the island-shaped TFT as shown in FIG. 5, the partial thickness of the semiconductor layer 14 corresponding to the channel A may proceed to be further etched and removed. This depends on the purpose of use, and is an optional step.

In the method of the present invention, the material of gate insulation layer 13 may be a material commonly used in the insulation material of TFT. For example, it may be silicon nitride, SiO₂, SiOₓN_{y}, aluminum oxide, Ta₂O, organic materials as polyamide, or high-K dielectric material as Barium Strontium Titanate (BST), Barium Zirconium Titanate (BZT), and Ta₂O₅. The ohmic contact layer can made of material as n+silicon or p+silicon, and the n+silicon is preferred.

In the method of the present invention, the material of semiconductor layer may be amorphous silicon (a-Si, a-Si:H), polysilicon, or other semiconductor material for forming a current channel in a transistor.

In accordance with the present invention, the main objective is to define the channel A between the drain and the source by means of back exposure through the transparent conductive material. The material of the transparent conductive layer 16 can be any kinds of conventional transparent conductive material; however, indium tin oxidize (ITO) or indium zinc oxidize (IZO) may be widely used, and IZO is preferred.

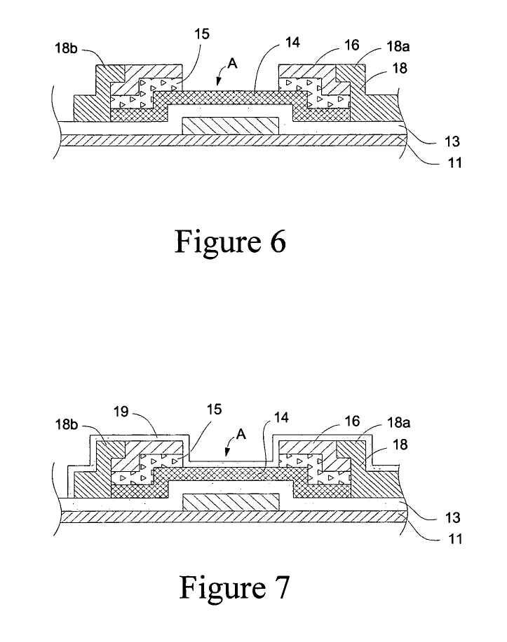

Please refer to FIG. 6, a second metal layer 18 is formed on the structure as shown in FIG. 5 before forming the passivation layer 19. Using a positive photoresist and a mask with a desired pattern, the second metal layer 18 on the channel A is removed by front exposure to form the drain wire 18a and the source wire 18b. Moreover, the transparent conductive layer 16 made of ITO would form a “Buffer Zone” contact for the second metal layer 18. The gap between the source wire 18b and the drain wire 18a can be designed wider since the “Buffer Zone” contact would make the source/drain of TFT aligned perfectly with the portion U; so the uneven parasitic of capacitance (Cgd) problem in the conventional art is eliminated.

Lastly, a passivation layer 19 is blanket formed on the TFT as shown in FIG. 7, and fabricating the self-aligned TFT of the LCD substrate in the present invention is completed.

Furthermore, the formation of the second metal layer 18 as shown in FIG. 6 and the formation of the passivation layer 19 as shown in FIG. 7 are both optional steps. However, they could improve the performance of TFT function well.

According to the method for fabricating the self-aligned TFT of the present invention, the etching steps shown in FIG. 4 can be performed to only etch the transparent conductive layer 16, and the ohmic contact layer 15 below the etched region (channel A region) of the transparent conductive layer 16 is temporally remained without being etched. After the steps of forming the island shaped TFT as shown in FIG. 5, the ohmic contact layer 15 corresponding to the channel A is removed by etching to uncover the semiconductor layer 14. Briefly, the timing of etching the ohmic contact layer 15 is not subjected to before coating the passivation layer 19.

In the present invention, the etching method can be either dry etching or wet etching.

According to the present invention, the manufactured TFT according to the present invention is mainly used in the LCD device. However, the purpose of the present invention is not limited to LCD manufacturing field.

The present invention for fabricating the self-aligned TFT has been clarified clearly in the embodiments above. It will be obvious to those skilled in the art that various modifications may be made without departing from what is intended to be limited solely by the appended claims.

1. A method for fabricating a self-aligned TFT, comprising:
providing a transparent substrate;
forming a metal gate layer on a surface of said transparent substrate;
forming an insulation layer, a semiconductor layer, and a transparent conductive layer in sequence on said metal gate layer;
forming a negative photoresist layer on said transparent conductive layer;
exposing said negative photoresist layer from the reverse side of said surface of said transparent substrate by using said metal gate layer as a mask;
removing unexposed portion of said negative photoresist layer to uncover a portion of said transparent conductive layer;
etching said uncovered portion of said transparent conductive layer till a portion of said semiconductor layer is uncovered;
removing said negative photoresist layer; and
etching portions of said semiconductor layer, and said transparent conductive layer to form a TFT, wherein parasitic capacitance between said metal gate layer and said transparent conductive layer can be eliminated.

2. The method according to claim 1, further comprising a step of forming a second metal layer as source wire and drain wire on said transparent conductive layer after said step of etching said semiconductor layer and said transparent conductive layer to form said TFT.

3. The method according to claim 2, further comprising a step of forming a passivation layer on said TFT.

4. The method according to claim 1, further comprising a step of forming an ohmic contact layer between said semiconductor layer and said transparent conductive layer, and a step of etching said uncovered portion of said ohmic contact layer till a portion of said semiconductor layer being uncovered.

5. The method according to claim 2, wherein material of said gate layer is Cr, W, Al, Cu, Mo, or the combination thereof.

6. The method according to claim 2, wherein material of said transparent substrate is glass, quartz, plastics, or the combination thereof.

7. The method according to claim 2, wherein material of said transparent conductive layer is ITO, IZO, or the combination thereof.

8. The method according to claim 2, wherein thickness of said uncovered portion of said semiconductor layer is thinner than other portion of said semiconductor.

9. The method according to claim 2, wherein a shape of said gate is taper-shaped.

10. The method according to claim 2, wherein material of said insulation layer is silicon nitride, SiO₂, SiOₓN_{y}, aluminum oxide, Ta₂O, polyamide, BST, BZT, Ta₂O₅, or the combination thereof.

11. The method according to claim 1, wherein said TFT is island-shaped.

12. The method according to claim 1, wherein said step of etching said uncovered portion of said transparent conductive layer is performed by using wet etching.

13. A method for fabricating a self-aligned TFT, comprising:
providing a transparent substrate;
forming a metal gate layer on a surface of said transparent substrate;
forming an insulation layer, a semiconductor layer, an ohmic contact layer, and a transparent conductive layer in sequence on said metal gate layer;
forming a negative photoresist layer on said transparent conductive layer;
exposing said negative photoresist layer from the reverse side of said surface of said transparent substrate by using said metal gate layer as a mask;
removing unexposed portion of said negative photoresist layer to uncover a portion of said transparent conductive layer;
etching said uncovered portion of said transparent conductive layer till a portion of said ohmic contact layer is uncovered;
removing said negative photoresist layer;
etching portions of said semiconductor layer, said ohmic contact layer, and said transparent conductive layer to form a TFT;
forming a second metal layer and removing a portion of said second metal layer to form a source wire and a drain wire of said TFT; and
forming a passivation layer on said TFT, wherein parasitic capacitance between said metal gate layer and said transparent conductive layer can be eliminated.

14. The method according to claim 13, wherein said material of said gate layer is Cr, W, Al, Cu, Mo, or the combination thereof.

15. The method according to claim 13, wherein said material of said insulation layer is silicon nitride, SiO₂, SiOₓN_{y}, aluminum oxide, Ta₂O, polyamide, BST, BZT, Ta₂O₅, or the combination thereof.

16. The method according to claim 13, wherein said drain wire and said source wire are formed by front exposure.

17. A thin film transistor, comprising:
a transparent substrate;
a metal gate formed on said transparent substrate;
an insulation layer formed on said transparent substrate and said metal gate;
a semiconductor layer formed on said insulation layer; and
a transparent conductive layer formed on said semiconductor layer, and said transparent conductive layer having two separated portions, wherein said two portions are on two sides of said metal gate and an interval between said two portions is substantially equal to a width of said metal gate, wherein parasitic capacitance between said metal gate layer and said transparent conductive layer can be eliminated.

18. The thin film transistor according to claim 17, further comprising a metal layer formed on said two portions of said transparent conductive layer.

19. The thin film transistor according to claim 18, wherein said metal layer has a gap wider than said interval.

20. The thin film transistor according to claim 17, further comprising a passivation layer formed over said transparent conductive layer.
